(19) United States
(12) Patent Application Publication
(10) Pub. No.: US 2025/0006679 A1
(43) Pub. Date: Jan. 2, 2025

(54) CONDUCTIVE MATERIALS FOR DIRECT BONDING

(71) Applicant: ADEIA SEMICONDUCTOR BONDING TECHNOLOGIES INC., San Jose, CA (US)

(72) Inventors: Jeremy Alfred Theil, Mountain View, CA (US); Cyprian Emeka Uzoh, San Jose, CA (US); Guilian Gao, Campbell, CA (US); Belgacem Haba, Saratoga, CA (US); Laura Wills Mirkarimi, Sunol, CA (US)

(21) Appl. No.: 18/391,173

(22) Filed: Dec. 20, 2023

Related U.S. Application Data
(60) Provisional application No. 63/524,564, filed on Jun. 30, 2023.

(51) Int. Cl. H01L 23/00

(52) U.S. Cl. CPC H01L 24/08; H01L 24/03; H01L 24/05; H01L 24/80; H01L 2224/0219; H01L 2224/03011; H01L 2224/05618; H01L 2224/05647; H01L 2224/05657; H01L 2224/05684; H01L 2224/08145; H01L 2224/80379; H01L 2224/80895; H01L 2224/80896

(57) ABSTRACT

A structure includes a first substrate including a first layer having at least one electrically conductive first portion and at least one electrically insulative second portion and a second substrate including a second layer having at least one electrically conductive third portion and at least one electrically insulative fourth portion. The structure further includes an interface layer having at least one electrically conductive oxide material between the first layer and the second layer. The at least one electrically conductive oxide material includes at least one first region between and in electrical communication with the at least one electrically conductive first portion and the at least one electrically conductive third portion, and at least one second region between the at least one electrically insulative second portion and the at least one electrically insulative fourth portion.

### BACKGROUND

### Field

The field relates to systems and methods for wafer-to-wafer, die-to-die, and/or die-to-wafer hybrid bonding for semiconductor devices and optoelectronic devices.

### Description of the Related Art

Semiconductor elements, such as semiconductor wafers or integrated device dies, can be stacked and directly bonded to one another without an adhesive, thereby forming a bonded structure. Nonconductive (e.g., dielectric; semiconductor) surfaces can be made extremely smooth and treated to enhance direct, covalent bonding, even at room temperature and without application of pressure beyond contact. In some hybrid bonded structures, nonconductive field regions of the elements can be directly bonded to one another, and corresponding conductive contact structures can be directly bonded to one another.

For example, a semiconductor element can be mounted to a carrier, such as a package substrate, an interposer, a reconstituted wafer or element, a flat panel, a glass, etc. A semiconductor element can be stacked on top of the semiconductor element (e.g., a first integrated device die can be stacked on a second integrated device die). Each of the semiconductor elements can have conductive pads for mechanically and electrically bonding the semiconductor elements to one another with the conductive pads mechanically and electrically bonded to one another.

### SUMMARY

Certain implementations described herein provide a structure comprising a first substrate comprising a first layer having at least one electrically conductive first portion and at least one electrically insulative second portion. The structure further comprises a second substrate comprising a second layer having at least one electrically conductive third portion and at least one electrically insulative fourth portion. The structure further comprises an interface layer between the first layer and the second layer. The interface layer comprises at least one electrically conductive oxide material. The at least one electrically conductive oxide material comprises at least one first region between and in electrical communication with the at least one electrically conductive first portion and the at least one electrically conductive third portion. The at least one electrically conductive oxide material further comprises at least one second region between the at least one electrically insulative second portion and the at least one electrically insulative fourth portion. The at least one second region is electrically isolated from the at least one first region.

Certain implementations described herein provide a structure comprising a first substrate having a first conductive feature comprising a first region of a first deposited electrically conductive oxide material. The structure further comprises a second substrate having a second conductive feature directly bonded to the first conductive feature.

Certain implementations described herein provide a method comprising providing a first substrate and a second substrate each comprising one or more electrically conductive surface portions and one or more electrically insulative surface portions. At least one of the first substrate and the second substrate further comprises an electrically conductive oxide layer having a first region over and in electrical communication with the one or more electrically conductive surface portions and a second region over the one or more electrically insulative surface portions. The second region is electrically isolated from the first region. The method further comprises directly bonding the first substrate and the second substrate with one another without an intervening adhesive. Said directly bonding the first substrate and the second substrate comprises contacting the first substrate and the second substrate with one another with the electrically conductive oxide layer therebetween.

Certain implementations described herein provide a method comprising providing a first substrate having a first patterned conductive contact feature. The first patterned conductive contact feature comprises a first region of a first electrically conductive oxide material. The method further comprises providing a second substrate having a second conductive contact feature. The method further comprises directly bonding the first conductive contact feature to the second conductive contact feature.

Certain implementations described herein provide a method comprising providing a first patterned conductive contact feature in a first substrate. The method further comprises providing a second patterned conductive contact feature in a second substrate. The method further comprises directly bonding the first patterned conductive contact feature to the second patterned conductive contact feature. The first substrate and the second substrate are not activated after the first patterned conductive contact feature is patterned and prior to the directly bonding.

Certain implementations described herein provide a method comprising providing a first patterned conductive contact feature in a first substrate. The method further comprises providing a second patterned conductive contact feature in a second substrate. The method further comprises directly bonding the first patterned conductive contact feature to the second patterned conductive contact feature. The first substrate is not planarized after the first conductive contact feature is patterned and before the directly bonding.

Certain implementations described herein provide a structure comprising a first substrate comprising a first layer comprising dielectric oxide portions and electrically conductive portions, a second substrate comprising a second layer comprising dielectric oxide portions and electrically conductive portions, and an interface layer between the first layer and the second layer. The interface layer comprises at least one electrically conductive oxide material and comprising first portions between the dielectric oxide portions of the first and second layers and second portions between the electrically conductive portions of the first and second layers, the first portions of the interface layer electrically isolated from the second portions of the interface layer.

Certain implementations described herein provide a method comprising providing a first element comprising a first surface layer comprising dielectric oxide portions and electrically conductive portions. The method further comprises providing a second element comprising a second surface layer comprising dielectric oxide portions and electrically conductive portions. The method further comprises depositing an electrically conductive oxide layer over at least one of the first surface layer and the second surface layer. The deposited layer comprises first portions over the dielectric oxide portions of at least one of the first surface layer and the second surface layers, and the deposited layer further comprises second portions over the electrically conductive portions of at least one of the first surface layer and the second surface layer. The first portions of the deposited layer are electrically isolated from the second portions of the deposited layer. The method further comprises directly bonding the first element and the second element with one another without an intervening adhesive. The directly bonding comprises bonding the first and second surface layers together with the electrically conductive oxide layer therebetween.

Certain implementations described herein provide a method comprising providing a first substrate having a first conductive contact feature. The first conductive contact feature comprises a first region of a first deposited electrically conductive oxide material. The method further comprises providing a second substrate having a second conductive contact feature. The method further comprises directly bonding the first conductive contact feature to the second conductive contact feature.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to bonding in accordance with certain implementations described herein.

FIG. 1B is a schematic cross-sectional side view of the two elements of FIG. 1A after bonding in accordance with certain implementations described herein.

FIGS. 2A and 2B schematically illustrate two cross-sectional views of an example structure in accordance with certain implementations described herein.

FIGS. 2C and 2D schematically illustrate cross-sectional views of other example structures in accordance with certain implementations described herein.

FIGS. 3A and 3B schematically illustrate two cross-sectional views of another example structure in accordance with certain implementations described herein.

FIGS. 3C and 3D schematically illustrate cross-sectional views of other example structures in accordance with certain implementations described herein.

FIGS. 4A and 4B schematically illustrate two cross-sectional views of another example structure in accordance with certain implementations described herein.

FIG. 4C schematically illustrates a cross-sectional view of another example structure in accordance with certain implementations described herein.

FIGS. 4D-4F schematically illustrate cross-sectional views of a section of an example die, an example first die layout, and an example second die layout in accordance with certain implementations described herein.

FIG. 5 is a flow diagram of an example method for forming a structure compatible with certain implementations described herein.

FIGS. 6A and 6B schematically illustrate the example method of FIG. 5 for forming the example structures of FIGS. 2A and 2B in accordance with certain implementations described herein.

FIGS. 7A and 7B schematically illustrate the example method of FIG. 5 for forming the example structures of FIGS. 3A and 3B in accordance with certain implementations described herein.

FIGS. 8A and 8B schematically illustrate still another example of the method of FIG. 5 for forming structures in accordance with certain implementations described herein.

FIGS. 9A and 9B schematically illustrate another example structure and method for forming the structure in accordance with certain implementations described herein.

FIG. 10 schematically illustrates an example build-up process flow for forming the structure in accordance with certain implementations described herein.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

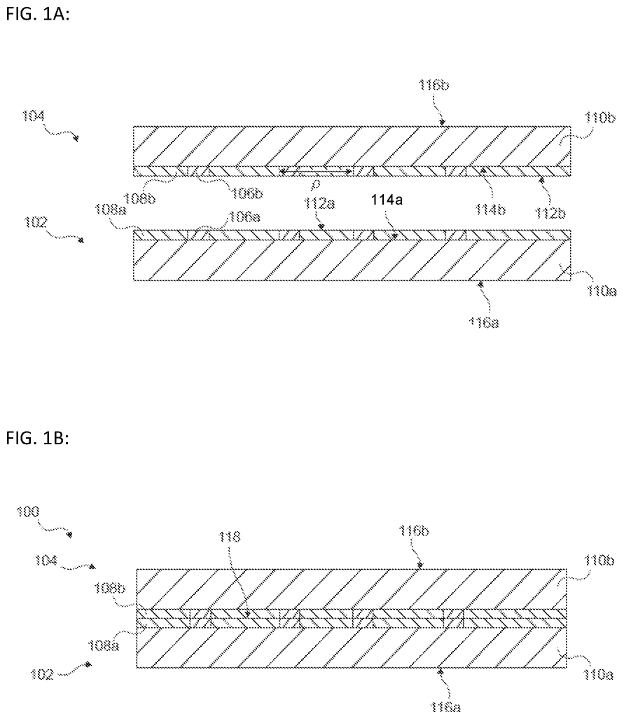

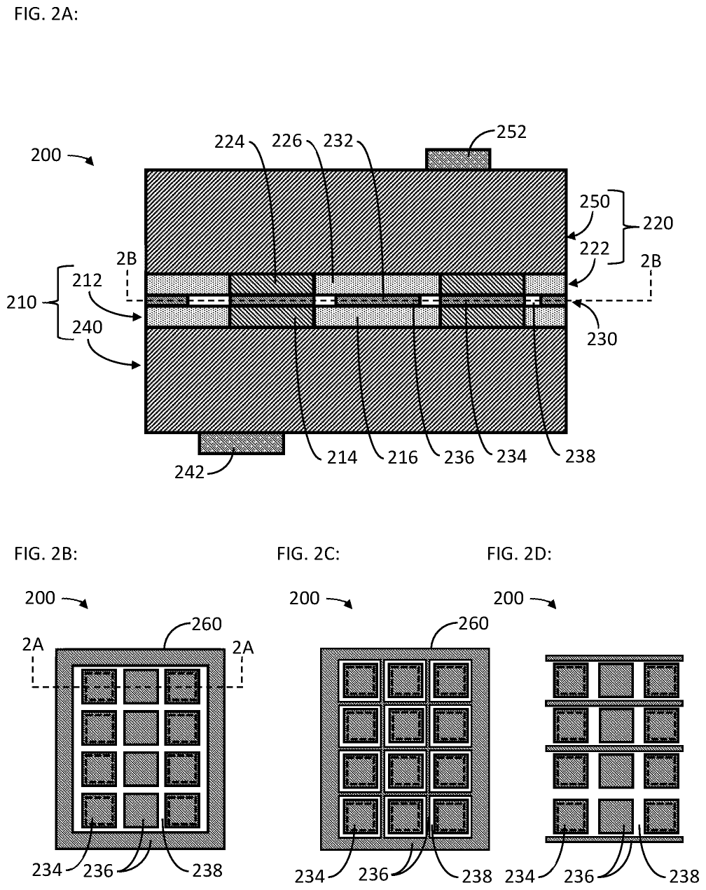

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

Certain implementations disclosed herein relate to optoelectronic devices that include directly bonded contacts comprising optically transparent or optically semi-transparent electrically conducting material (referred to herein collectively as transparent conductors or TCs) instead of metal direct bonded contacts. For example, the optoelectronic devices can include optical elements or devices (e.g., photodiodes; light emitting diodes (LEDs)); quantum dot light emitting diodes (QLEDs); lasers; vertical-cavity surface-emitting lasers (VCSELs); transparency control pixels; liquid crystal pixels; adaptive optics; solar cells; waveguides; spatial light modulators; diode lasers; electrochromic devices) that are stacked on or bonded to one another to form a bonded structure. The TCs on separate substrates can be planarized and the planarized surfaces of the substrates can be placed in contact with one another, as described herein, to form the bonded structures.

In certain implementations, the optoelectronic devices described herein are configured to be used in various contexts which are area-limited (e.g., displays for virtual reality (VR) or augmented reality (AR) applications; multijunction solar cells) or other designs comprising an optoelectronic (e.g., electro-optical) element within a stack of other optical elements, beneficially utilizing the TCs for providing electrical connection between electrical elements while not appreciably blocking light.

As used herein, the term “optically transparent” includes but is not limited to optically translucent, optically semi-transparent, and/or having an optical transmittance of at least 50% (e.g., at least 60%; at least 75%; at least 88%; greater than or equal to 95%) at optical wavelengths in a predetermined range. For example, the predetermined range for optically transparent components (e.g., elements; substrates; layers; devices; features) can be visible wavelengths (e.g., 390 nanometers to 750 nanometers; 400 nanometers to 700 nanometers), ultraviolet wavelengths (e.g., 100 nanometers to 400 nanometers), infrared wavelengths (e.g., 800 nanometers to 1 millimeter), and/or short-wave infrared (SWIR) wavelengths (e.g., 1400 nanometers to 3000 nanometers).

As described herein, some electrically conductive oxides (e.g., indium tin oxide or ITO) or nitrides have the ability to self-bond at modest temperatures (e.g., in a range of 75° C. to 400° C.; in a range of 120° C. to 300° C.; in a range of 150° C. to 300° C.). In certain implementations, use of electrically conductive oxide or nitride layers can simplify processes for bonding (e.g., blanket wafer and hybrid bonding surfaces) by omitting one or more other processing steps (e.g., planarization and/or surface activation). For example, the electrically conductive oxide or nitride layers can be self-leveled if planarized before patterning. In conjunction with certain layout structures, such electrically conductive oxide or nitride layers can be used to bond multiple input/output components with a single material interface. For example, ITO can be used to bond two substrates without a surface activation step, and in certain implementations, without a surface planarization (e.g., chemical-mechanical polishing or CMP) step. The electrically conductive oxide or nitride layers can also allow bonding at modest temperatures (e.g., less than 300° C.) and can be used for surface mounting. In view of the electrical conductivity, such layers can provide electromagnetic shielding for other components of the electronic packages. In addition, because certain such materials are substantially optically transparent, they can be used for bonding optoelectronic applications, as well as in other structures where photon transmission is not a factor.

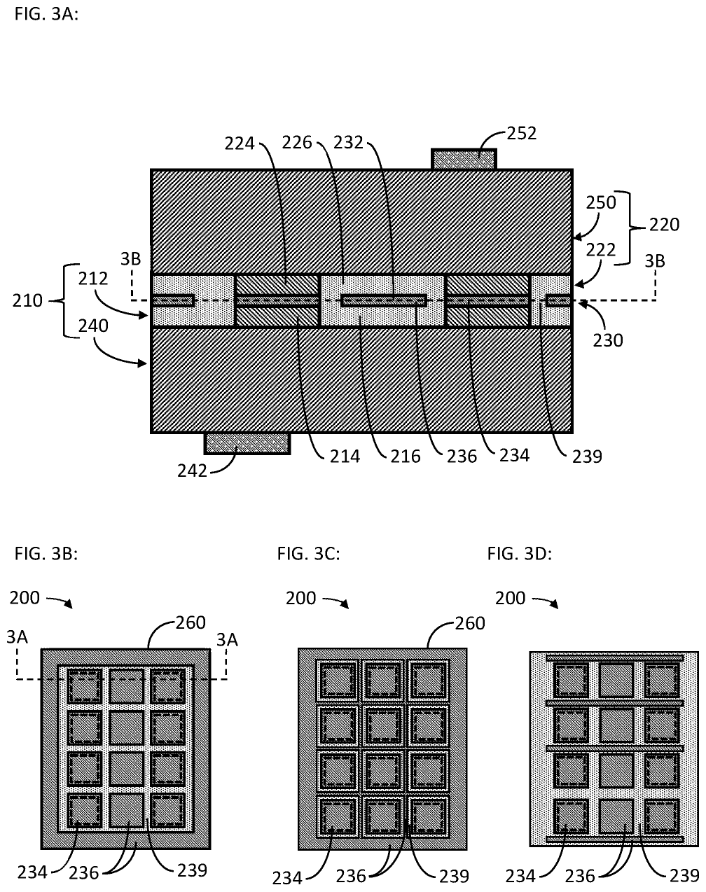

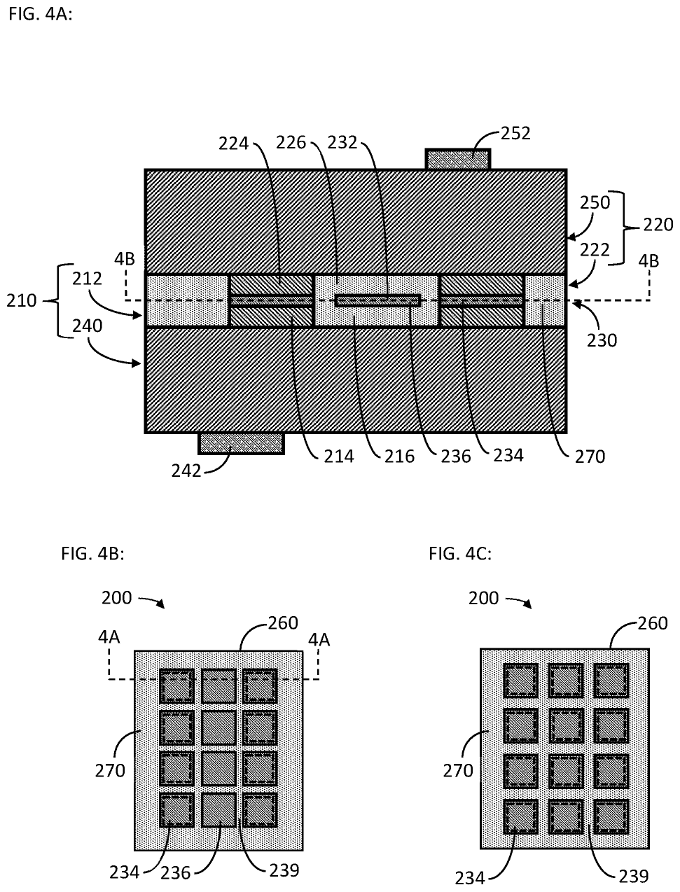

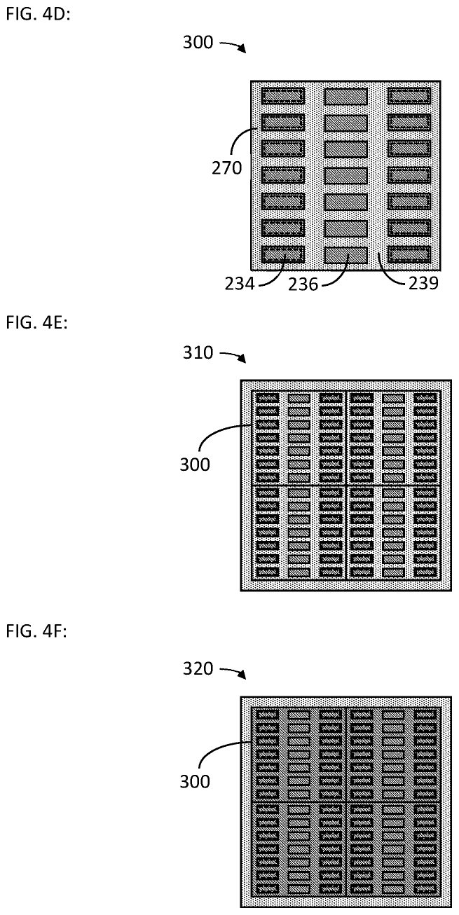

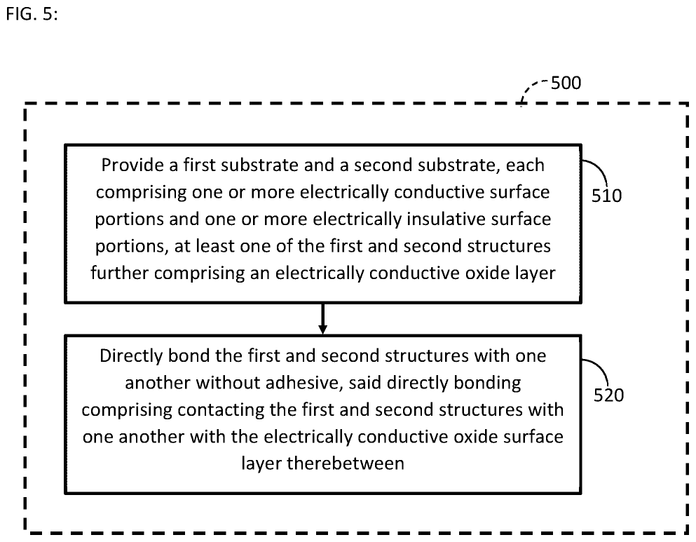

FIGS. 2A and 2B schematically illustrate two cross-sectional views of an example structure 200 in accordance with certain implementations described herein, and FIGS. 3A and 3B schematically illustrate two cross-sectional views of another example structure 200 in accordance with certain implementations described herein. The cross-sectional views of FIGS. 2A and 3A are in a first plane and the cross-sectional views of FIGS. 2B and 3B are in a second plane (e.g., a cross-sectional plan view) substantially perpendicular to the first plane of FIGS. 2A and 3A, respectively. The structure 200 comprises a first substrate 210 (e.g., first element 102) comprising a first layer 212 having at least one electrically conductive first portion 214 (e.g., conductive feature 106a) and at least one electrically insulative second portion 216. The structure 200 further comprises a second substrate 220 (e.g., second element 104) comprising a second layer 222 having at least one electrically conductive third portion 224 (e.g., conductive feature 106b) and at least one electrically insulative fourth portion 226. The structure 200 further comprises an interface layer 230 between the first layer 212 and the second layer 222 (e.g., formed by direct bonding of two opposing layers of at least one electrically conductive oxide material 232). The interface layer 230 comprises at least one electrically conductive oxide material 232. The at least one electrically conductive oxide material 232 comprises at least one first region 234 between and in electrical communication with the at least one electrically conductive first portion 214 and the at least one electrically conductive third portion 224. The at least one electrically conductive oxide material 232 further comprises at least one second region 236 between the at least one electrically insulative second portion 216 and the at least one electrically insulative fourth portion 226.

In certain implementations, the first substrate 210 comprises at least one first device 240 and the second substrate 220 comprises at least one second device 250. The at least one first device 240 and/or the at least one second device 250 can be optically transparent (e.g., optoelectronic device; optoelectronic element; electro-optical element; solar cell) or can be optically non-transparent (e.g., opaque). The at least one first device 240 and/or the at least one second device 250 can further comprise electrical conduits (e.g., optically transparent; non-optically transparent). In certain implementations, the first substrate 210 comprises at least one electrical contact 242 (e.g., a large lateral area contact on a backside 116a of the corresponding device portion 110a) in electrical communication with the at least one first device 240 and the second substrate 220 comprises at least one electrical contact 252 (e.g., on a backside 116b of the corresponding device portion 110b) in electrical communication with the at least one second device 250. The electrical contacts 242, 252 can be configured to transmit electrical signals to and/or from the first and/or second devices 240, 250. Example materials for the electrical contacts 242, 252 include but are not limited to copper or copper alloys, although other metals and alloys may be suitable. In addition, the electrical contacts 242, 252 can comprise additional electrically conductive layers between the copper and the corresponding at least one first and/or second device 240, 250. In certain implementations, at least one of the electrical contact 242, 252 comprises an electro-optical (EO) contact comprising a transparent and electrically conductive material (e.g., an electrically conductive oxide material as disclosed herein) that is in electrical and optical communication with the at least one first device 240 and the at least one second device 250, respectively, to transmit electrical and optical signals to and/or from the first and/or second devices 240, 250.

In certain implementations, the at least one electrically conductive first portion 214 and/or the at least one electrically conductive third portion 224 comprises at least one electrically conductive material, examples of which include, but are not limited to: copper; tungsten; cobalt; doped and undoped metal oxides; aluminum zinc oxide (AZO); indium tin oxide (ITO, In₂O₃); zinc oxide (ZnO); zinc tin oxide (ZnSnO₃, Zn₂SnO₄); indium-doped zinc oxide (IZO); indium oxide; cadmium tin oxide (Cd₂SnO₄); tin oxide (SnO₂); titanium dioxide (TiO₂); niobium-doped titanium dioxide (Nb—TiO₂); titanium nitride (TiN); tin nitride (Sn₃N₄); other metal nitrides (e.g., A₃N₂ where A=Mg, Zn, Sn); transition metal nitrides comprising a IIIB, IVB, or VB transition metal. In certain implementations, the first and/or third portions 214, 224 are optically transparent, while in certain other implementations, the first and/or third portions 214, 224 are optically non-transparent (e.g., opaque). Each of the first portions 214 and/or the third portions 224 can comprise a single layer or multiple layers. The first and third portions 214, 224 can comprise the same electrically conductive material or can comprise different electrically conductive materials (e.g., materials having different elemental constituents and/or different stoichiometries). The electrically conductive materials of the first and/or third portions 214, 224 can be different from the electrically conductive oxide material 232, and the bonding of the first and/or third portions 214, 224 with the interface layer 230 can comprise hybrid bonding.

In certain implementations, the at least one electrically insulative second portion 216 and/or the at least one electrically insulative fourth portion 226 comprises at least one dielectric material (e.g., an inorganic dielectric material), examples of which include, but are not limited to: semiconductor oxides; semiconductor nitrides; silicon oxide (SiO₂); silicon nitride (SiNₓ, Si₃N₄); silicon oxycarbonitride (SiOₓN_{y}C_{z}); titanium oxide. In certain implementations, the second and/or fourth portions 216, 226 are optically transparent, while in certain other implementations, the second and/or fourth portions 216, 226 are optically non-transparent (e.g., opaque). Each of the second portions 216 and/or the fourth portions 226 can comprise a single layer or multiple layers. The second and fourth portions 216, 226 can comprise the same dielectric material or can comprise different dielectric materials (e.g., materials having different elemental constituents and/or different stoichiometries). The dielectric materials of the second and/or fourth portions 216, 226 are different from the electrically conductive oxide material 232, and the bonding of the second and/or fourth portions 216, 226 with the interface layer 230 can comprise hybrid bonding.

In certain implementations, the at least one electrically conductive oxide material 232 is selected from the group consisting of: indium tin oxide (ITO); zinc oxide (ZnO); indium-doped zinc oxide (IZO); tin oxide (SnO₂). In certain implementations, the at least one electrically conductive oxide material 232 is optically transparent, while in certain other implementations, the at least one electrically conductive oxide material 232 is optically non-transparent (e.g., opaque). As described herein, the at least one electrically conductive oxide material 232 can comprise a first electrically conductive oxide material 232a on the first layer 212 and a second electrically conductive oxide material 232b on the second layer 222, and the interface layer 230 can be formed by directly bonding the first electrically conductive oxide material 232a to the second electrically conductive oxide material 232b. In certain implementations, the interface layer 230 has a thickness in a range of 5 nm to 3 microns. In certain implementations, the resistivity of the electrically conductive oxide is in a range less than 500×10⁻⁶ Ω-cm (e.g., 200×10⁻⁶ Ω-cm to 40×10⁻⁶ Ω-cm; 500×10⁻⁶ Ω-cm to 20×10⁻⁶ Ω-cm; in a range less than 120×10⁻⁶ Ω-cm). In certain implementations, the optical transmission within the wavelength range of interest is greater than 40% (e.g., greater than 60%; greater than 80%).

In certain implementations, the interface layer 230 is patterned such that the at least one first region 234 is electrically isolated from the at least one second region 236. For example, as schematically illustrated by FIGS. 2A and 2B, the structure 200 further comprises gaps 238 between the at least one first region 234 and the at least one second region 236. In certain implementations, the gaps 238 comprise gas (e.g., air; nitrogen) and can be at atmospheric pressure, less than atmospheric pressure (e.g., vacuum pressure), or greater than atmospheric pressure. As schematically illustrated by FIG. 2A, the at least one electrically conductive oxide material 232 is not embedded within the at least one electrically insulative second portion 216 and/or the at least one electrically insulative fourth portion 226.

For another example, as schematically illustrated by FIGS. 3A and 3B, the interface layer 230 comprises at least one solid dielectric material 239 (e.g., silicon oxycarbonitride or SiOₓN_{y}C_{z}) between the at least one first region 234 and the at least one second region 236. The at least one solid dielectric material 239 can be different from the materials of the at least one electrically insulative second portion 216 and/or the at least one electrically insulative fourth portion 226, or the at least one solid dielectric material 239 can be the same as the material of the at least one electrically insulative second portion 216 and/or the at least one electrically insulative fourth portion 226. As schematically illustrated by FIG. 3A, the at least one conductive oxide material 232 is at least partially embedded (e.g., fully embedded) within the at least one electrically insulative second portion 216 and/or the at least one electrically insulative fourth portion 226.

In the cross-sectional views of FIGS. 2B and 3B, the first regions 234 of the at least one electrically conductive oxide material 232 have dashed lines (denoting the underlying and overlying first and third portions 214, 224) to distinguish them from the second regions 236 of the at least one electrically conductive oxide material 232 (which have underlying and overlying second and fourth portions 216, 226). As shown in FIGS. 2B and 3B, the first regions 234 are electrically isolated from the second regions 236 and from one another (e.g., by the gaps 238 of FIG. 2A or by the at least one solid dielectric material 239 of FIG. 3A) such that the interface layer 230 does not electrically short the first portions 214 to one another and does not electrically short the third portions 224 to one another.

FIGS. 2C, 2D, 3C, and 3D schematically illustrate cross-sectional plan views of other example structures 200 in accordance with certain implementations described herein. Similar to FIGS. 2B and 3B, the cross-sectional views of FIGS. 2C, 2D, 3C, and 3D are in the second plane that is substantially perpendicular to the first plane of FIGS. 2A and 3A. As shown in FIGS. 2C, 2D, 3C, and 3D, at least some second regions 236 of the at least one electrically conductive oxide material 232 can be between at least some adjacent first regions 234 of the at least one electrically conductive oxide material 232 (e.g., between each adjacent pair of first regions 234 as shown in FIGS. 2C and 3C). As shown in FIGS. 2B, 2C, 3B, and 3C, a portion of the at least one electrically conductive oxide material 232 (e.g., the second regions 236) can be at a periphery 260 of the first and second substrates 210, 220. In certain implementations (see, e.g., FIGS. 2B, 2C, 3B, and 3C), the portion of the at least one electrically conductive oxide material 232 at the periphery 260 substantially surrounds (e.g., encircles) the first and/or second regions 234, 236 and can be configured to hermetically seal a second portion of the at least one electrically conductive oxide material 232 from an ambient environment (e.g., outside the periphery 260). As shown in FIGS. 2D and 3D, the at least one electrically conductive oxide material 232 can be spaced from the periphery 260 and/or does not substantially surround (e.g., encircle) the first and/or second regions 234, 236 or hermetically seal other portions of the at least one electrically conductive oxide material 232 from the ambient environment.

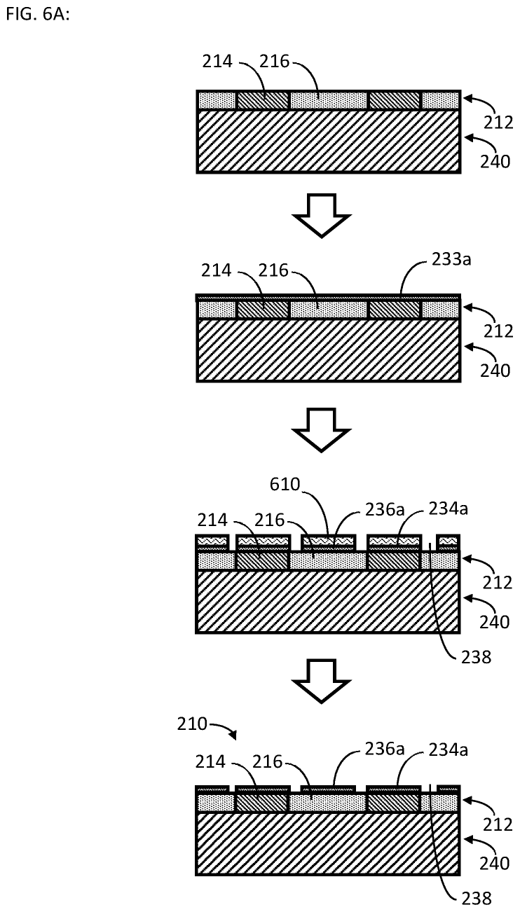

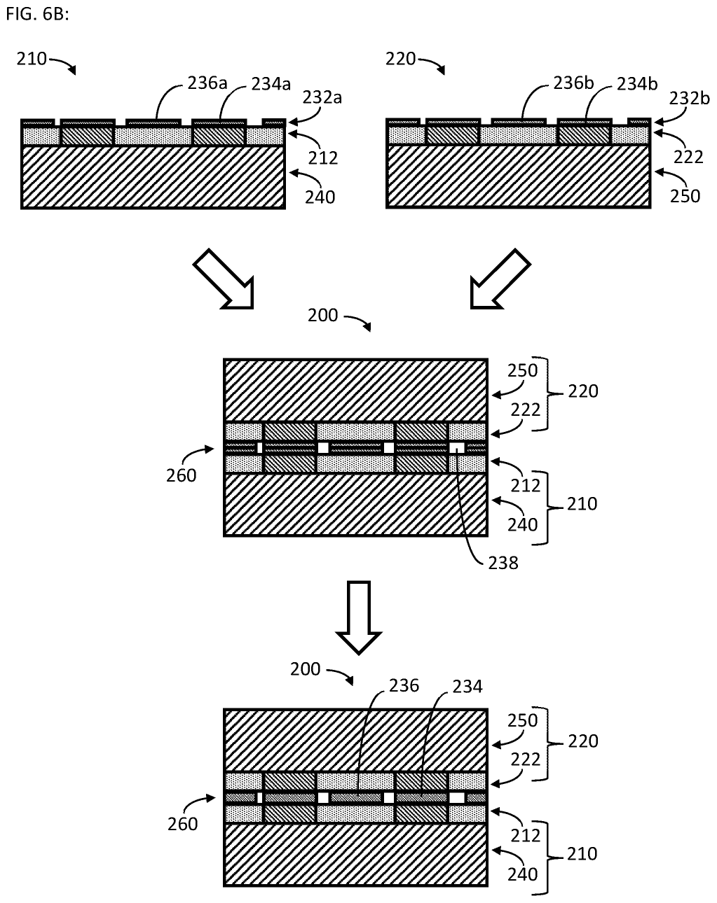

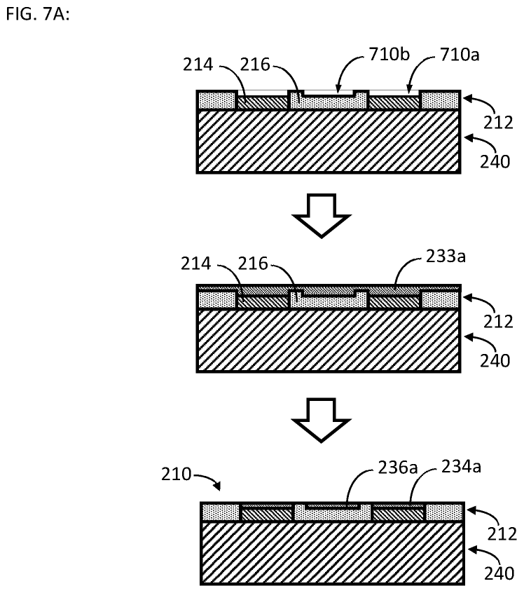

FIGS. 4A and 4B schematically illustrate two cross-sectional views of another example structure 200 in accordance with certain implementations described herein. The cross-sectional views of FIG. 4A is in a first plane and the cross-sectional views of FIG. 4B is in a second plane substantially perpendicular to the first plane of FIG. 4A. As schematically illustrated by FIG. 4A, the at least one conductive oxide material 232 is embedded within the at least one electrically insulative second portion 216 and/or the at least one electrically insulative fourth portion 226 (e.g., in the at least one solid dielectric material 270). FIG. 4C schematically illustrates a cross-sectional view of another example structure 200 in accordance with certain implementations described herein. Similar to FIG. 4B, the cross-sectional views of FIG. 4C is in the second plane that is substantially perpendicular to the first plane of FIG. 4A.

In certain implementations (e.g., as shown in FIGS. 4A-4C), a portion of the solid dielectric material 270 (e.g., silicon oxycarbonitride or SiOₓN_{y}C_{z}) of the first layer 212 is at a periphery 260 of the first and second substrates 210, 220. The solid dielectric material at the periphery 260 substantially surrounds (e.g., encircles) the at least one first region 234 and/or the at least one second region 236 and can be configured to hermetically seal the at least one first region 234 and/or the at least one second region 236 from the ambient environment (e.g., outside the periphery 260).

FIGS. 4D-4F schematically illustrate cross-sectional views of a section of an example die 300, an example first die layout 310, and an example second die layout 320 in accordance with certain implementations described herein. The cross-sectional views of FIGS. 4D-4F are in the second plane substantially perpendicular to the first plane of FIG. 4A. In FIGS. 4D-4F, the first portions 214 of the first layer 212 are embedded in the solid dielectric material 270 of the second portions 216 of the first layer 212, the third portions 224 of the second layer 222 are embedded in the solid dielectric material 270 of the fourth portions 226 of the second layer 222, with the first and second regions 234, 236 of the at least one electrically conductive oxide material 232 between the first layer 212 and the second layer 222. In the first die layout 310 of FIG. 4E, the at least one electrically conductive oxide material 232 is patterned such that the first portions 214 are electrically insulated from one another and the third portions 224 are electrically insulated from one another. In the second die layout 320 of FIG. 4F, the at least one electrically conductive oxide material 232 electrically connects multiple underlying first portions 214 to one another and/or electrically connects multiple overlying third portions 224 to one another. In the die 300, first die layout 310, and second die layout 320, the solid dielectric material 270 substantially surrounds (e.g., encircles) the at least one electrically conductive oxide material 232, hermetically sealing the first and second regions 234, 236 from the ambient environment (e.g., providing a hermetic seal ring). In certain implementations, the solid dielectric material 270 (e.g., silicon oxycarbonitride or SiOₓN_{y}C_{z}) provides higher hermeticity (e.g., lower gas leak rate) than would the at least one electrically conductive oxide material 232.

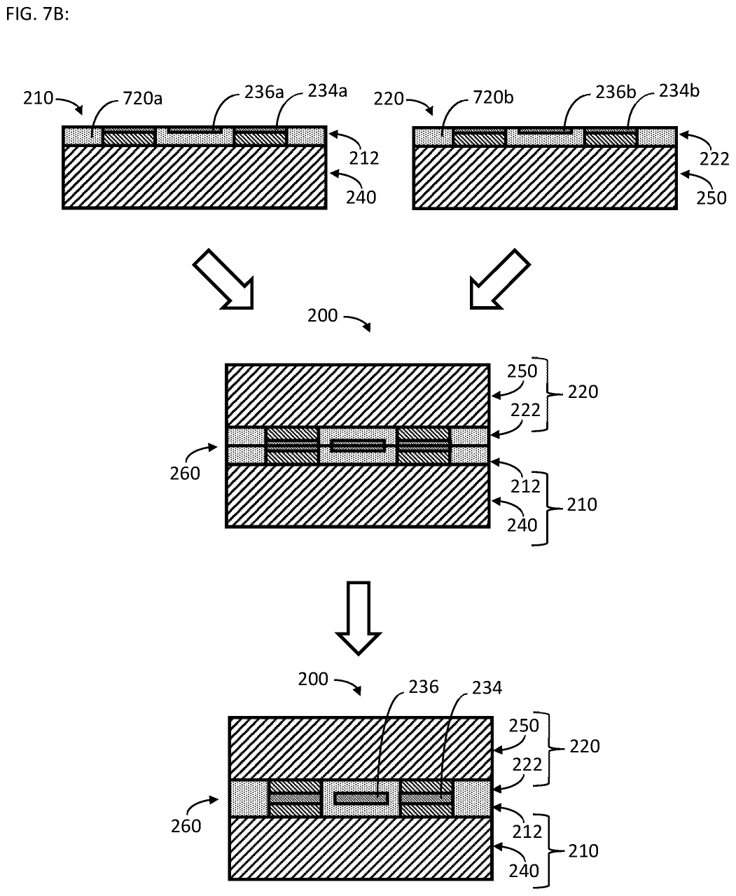

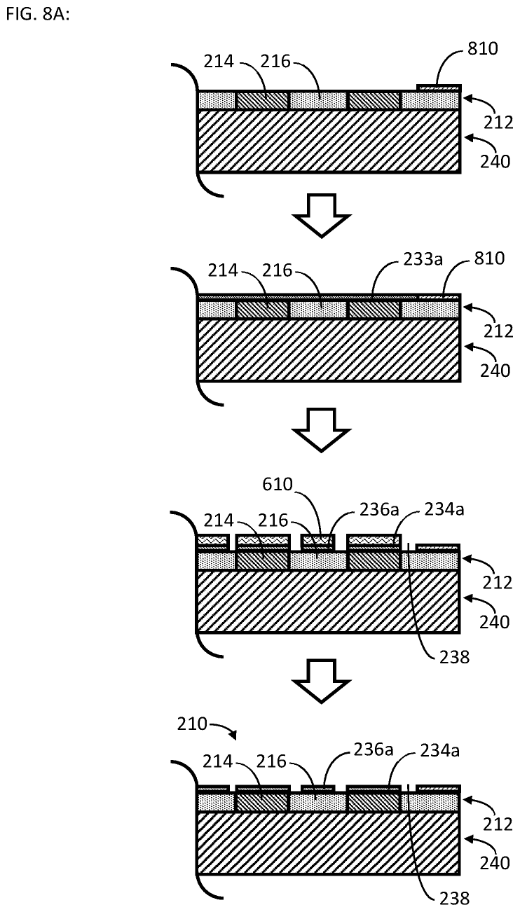

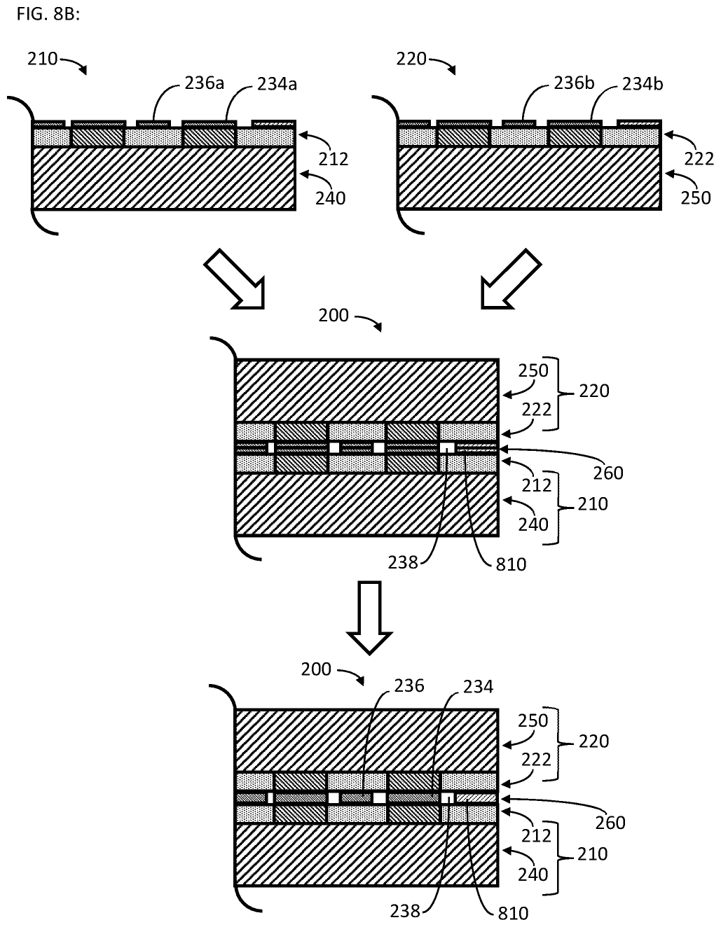

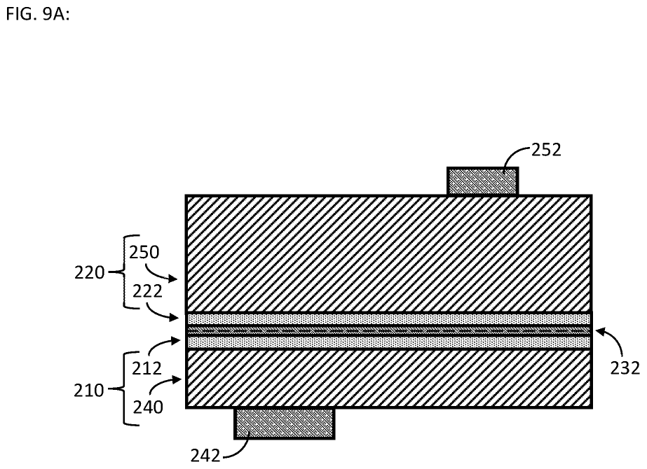

FIG. 5 is a flow diagram of an example method 500 for forming a structure 200 compatible with certain implementations described herein. FIGS. 6A and 6B schematically illustrate an example of the method 500 forming the example structures 200 of FIGS. 2A and 2B in accordance with certain implementations described herein. FIGS. 7A and 7B schematically illustrate another example of the method 500 forming the example structures 200 of FIGS. 3A and 3B in accordance with certain implementations described herein. FIGS. 8A and 8B schematically illustrate still another example of the method 500 forming the example structures 200 in accordance with certain implementations described herein. While the example method 500 is described herein by referring to the various example structures of FIGS. 2A, 2B, 3A, and 3B, other structures are also compatible with the example method 500 in accordance with certain implementations described herein.

In an operational block 510, the method 500 comprises providing a first substrate 210 (e.g., first element 102) and a second substrate 220 (e.g., second element 104). The first substrate 210 comprises one or more electrically conductive surface portions (e.g., first portions 214; conductive features 106a) and one or more electrically insulative surface portions (e.g., second portions 216) and the second substrate 220 comprises one or more electrically conductive surface portions (e.g., third portions 224; conductive features 106b) and one or more electrically insulative surface portions (e.g., fourth portions 226). At least one of the first substrate 210 and the second substrate 220 further comprises an electrically conductive oxide layer (e.g., an interface layer 230 comprises at least one electrically conductive oxide material 232) having a first region 234 over and in electrical communication with the one or more electrically conductive surface portions and a second region 236 over the one or more electrically insulative surface portions, the second region 236 electrically isolated from the first region 234. In an operational block 520, the method 500 further comprises directly bonding the first substrate 210 and the second substrate 220 with one another without an intervening adhesive. The directly bonding comprises contacting the first substrate 210 and the second substrate 220 with one another with the electrically conductive oxide surface layer therebetween.

In certain implementations, after the room temperature bonding operation, the bonded substrate 100 is annealed at a temperature higher than the room temperature (e.g., in a range of 120° C. to 500° C.; in a range of 120° C. to 150° C.; in a range of 150° C. to 350° C.) for an annealing time in a range of 10 minutes to more than 2 hours (e.g., higher annealing temperatures using shorter annealing times). The annealing ambient can comprise at least one of: nitrogen, forming gas, hydrogen plasma, vacuum, or other predetermined ambient. The annealing chamber can comprise one or more ovens (e.g., rapid thermal anneal (RTA) ovens; microwave ovens; ovens for processing semiconductor wafers, flat panels, etc.). After the annealing process, the opposing first and second bonding layers 108a, 108b can be permanently bonded and the bond energy of their bond interface 118 is at least 1000 mJm⁻² (e.g., higher than 2000 mJm⁻²). Similarly, the opposing conductive features 106a, 106b can be mechanically bonded and electrically coupled to one another. The bond interface 118 at the bonded first and second bonding layers 108a, 108b can be linear or nonlinear within the bonded conductive features 106a, 106b. In certain implementations, the grain size of the annealed conductive features 106a, 106b is greater than 20% (e.g., greater than 30%) of a width of the bonded conductive features 106a, 106b.

In certain implementations, the first and second elements 102, 104 are annealed at a first temperature in a suitable oven, the first temperature sufficiently high to enlarge the grain structure of the conductive oxide before the bonding operation. The bonding surfaces of the first and second elements 102, 104 comprising conductive oxide with large grains can be cleaned and bonded. In certain such implementations, the cleaned surface can be activated before the bonding operation. The bonded first and second elements 102, 104 can be annealed at a second temperature that can be substantially equal to or greater than the first temperature. In certain implementations, the first and second elements 102, 104 are annealed at a first temperature (e.g., lower than 250° C.) before the planarization step to form smooth bonding surfaces 112a, 112b.

As schematically illustrated by FIGS. 6A, 7A, and 8A, the one or more electrically conductive surface portions can comprise the electrically conductive first portions 214 (e.g., Cu; Al; Cu alloy; Al alloy) of the first layer 212 on the at least one first device 240 and the one or more electrically insulative surface portions can comprise the electrically insulative second portions 216 (e.g., silicon oxycarbonitride or SiOₓN_{y}C_{z}) of the first layer 212 on the at least one first device 240. Similarly, the one or more electrically conductive surface portions can comprise the electrically conductive third portions 224 of the second layer 222 on the at least one second device 250 and the one or more electrically insulative surface portions can comprise the electrically insulative fourth portions 226 of the second layer 222 on the at least one second device 250. The top surfaces of the first portions 214 can be recessed (e.g., by less than 10 nanometers) relative to the top surfaces of the second portions 216 and/or the top surfaces of the third portions 224 can be recessed (e.g., by less than 10 nanometers) relative to the top surfaces of the fourth portions 226.

FIG. 6A schematically illustrates an example fabrication sequence of the operational block 510 for providing the first substrate 210. Providing the first substrate 210 in the operational block 510 can comprise depositing a first electrically conductive oxide layer 233a (e.g., ITO) over the first layer 212, with the first regions 234a over and in electrical communication with the one or more electrically conductive first portions 214 and the second regions 236a over the one or more electrically insulative second portions 216. For example, depositing the first electrically conductive oxide layer 233a can comprise sputtering, activated chemical vapor deposition (CVD), directional physical vapor deposition (PVD), or atomic layer deposition (ALD) to a thickness on the order of microns. In certain implementations, after depositing the first electrically conductive oxide layer 233a, the first electrically conductive oxide layer 233a can be planarized (e.g., using CMP; with a CMP rate of 50-60 nm/min for ITO).

Providing the first substrate 210 in the operational block 510 can further comprise patterning the first electrically conductive oxide layer 233a to electrically isolate the first regions 234a from the second regions 236a. For example, as shown in FIG. 6A, a photoresist layer 610 can be deposited on the first electrically conductive oxide layer 233a, the photoresist layer 610 can be patterned (e.g., using photolithographic techniques) to expose portions of the first electrically conductive oxide layer 233a, and the exposed portions of the first electrically conductive oxide layer 233a can be etched away to form gaps 238 between the first regions 234a and the second regions 236a (e.g., such that the second regions 236a do not electrically short the first regions 234a to one another). For example, patterning ITO can be performed using dilute HCl or HCl vapor in a plasma dry etch process or using Cl₂, BCl₃, CH₄, or H₂ as a dry etchant. After etching, the remaining photoresist layer 610 can be stripped off and the first substrate 210, including the first and second regions 234a, 236a of the first electrically conductive oxide layer 233a, can be cleaned (e.g., rinsed and spin dried) sufficiently for subsequent directly bonding.

While the example fabrication sequences of FIG. 6A is for fabricating the first substrate 210, starting with the first device 240 and the first layer 212, the same example fabrication sequences can be used for fabricating the second substrate 220, starting with the second device 250 and the second layer 222. For example, providing the second substrate 220 can comprise depositing a second electrically conductive oxide layer 233b over the second layer 222 with the first regions 234b over and in electrical communication with the one or more electrically conductive third portions 224 and the second regions 236b over the one or more electrically insulative fourth portions 226. In certain implementations, after depositing the second electrically conductive oxide layer 233b, the second electrically conductive oxide layer 233b can be planarized (e.g., using CMP). Said providing the second substrate 220 in the operational block 510 can further comprise patterning the second electrically conductive oxide layer 233b to electrically isolate the first regions 234b from the second regions 236b (e.g., depositing a photoresist layer on the second electrically conductive oxide layer 233b, patterning the photoresist layer 610 using photolithographic techniques to expose portions of the second electrically conductive oxide layer, and etching away the exposed portions of the second electrically conductive oxide layer to form gaps between the first regions 234b and the second regions 236b), such that the second regions 236b do not electrically short the first regions 234b to one another. After etching, the remaining photoresist layer can be stripped off and the second substrate 220, including the first and second regions 234b, 236b of the second electrically conductive oxide layer 233b, can be cleaned (e.g., rinsed and spin dried) sufficiently for subsequent directly bonding.

As schematically illustrated by FIG. 6B, directly bonding the first substrate 210 and the second substrate 220 with one another without an intervening adhesive comprises contacting the first and second substrates 210, 220 with one another with the at least one electrically conductive oxide surface layer therebetween (e.g., at room temperature; at temperatures below 35° C.). For example, as shown in FIG. 6B, the first patterned electrically conductive oxide layer 233a and the second patterned electrically conductive oxide layer 233b can be contacted with one another (e.g., with the first regions 234a, 234b contacting one another and the second regions 236a, 236b contacting one another). While FIG. 6B schematically illustrates certain implementations in which the second substrate 220 comprises the second electrically conductive oxide layer 233b over the second layer 222, in certain other implementations, the second substrate 220 does not comprise the second electrically conductive oxide layer 233b over the second layer 222, and directly bonding the first and second substrates 210, 220 with one another uses only the first electrically conductive oxide layer 233a between the first and second substrates 210, 220 (e.g., the first regions 234a in electrical contact with the first portions 214 and third portions 224 and the second regions 236a in contact with the second portions 216 and fourth portions 226). The alignment between the first regions 234 with the first and third portions 214, 224 and the alignment between the second regions 236 and the second and fourth portions 216, 226 can be sufficient to provide substantial electrical contact between the first and third portions 214, 224 where desired while avoiding electrically shorting the first regions 234 to one another (e.g., the alignment can be less than perfect).

In certain implementations, the method 500 can further comprise, after contacting the first and second substrates 210, 220 with one another, annealing the structure 200 (e.g., heating to a predetermined temperature higher than room temperature for a predetermined time period; at temperatures in a range of 120° C. to 300° C.). The annealing process can cause the electrically conductive oxide layers 233a, 233b to expand to increase contact pressure between opposing conductive regions. Annealing can additionally or alternatively cause grain growth across the bond interface such that the grains can migrate at least partially into the opposing element. In certain implementations, the method 500 does not comprise activating (e.g., exposing to a plasma and/or chemical etchants) at least one of the first and second electrically conductive oxide layers 233a, 233b (e.g., both of the electrically conductive oxide layers 233a, 233b) after the cleaning. As shown in FIG. 6B, the periphery 260 of the structure 200 comprises the electrically conductive oxide material 232 (e.g., ITO), which can provide hermiticity to the components within the region bounded by the periphery 260.

FIG. 7A schematically illustrates another example fabrication sequence of the operational block 510 for providing the first substrate 210. As shown in FIG. 7A, the first portions 214 of the first layer 212 comprise recesses 710a relative to the second portions 216 of the first layer 212 (e.g., the top surface of the first portions 214 is recessed relative to the top surface of the second portions 216 by a depth in a range of 3 nm to 40 nm; the recesses can be formed by Cu polishing), and recesses 710b (e.g., having a depth in a range of 3 nm to 40 nm) at the top surface of the second portions 216. Providing the first substrate 210 in the operational block 510 can comprise depositing a first electrically conductive oxide layer 233a (e.g., ITO; SnO) over the first layer 212, thereby substantially filling the recesses 710a, 710b with the first electrically conductive oxide material 232. For example, depositing the first electrically conductive oxide layer 233a can comprise sputtering, activated CVD, directional PVD, or ALD to a thickness on the order of microns. After depositing the first electrically conductive oxide layer 233a, the first electrically conductive oxide layer 233a can be planarized (e.g., using CMP) to remove the portions of the first electrically conductive oxide material 232 outside the recesses 710a, 710b, thereby forming the first regions 234a over and in electrical communication with the one or more electrically conductive first portions 214 and the second regions 236a over the one or more electrically insulative second portions 216. The top surface of the first electrically conductive oxide material 232 can be recessed relative to the top surface of the adjacent second portions 216 (e.g., in a range of 2 nanometers to 8 nanometers) to account for the differing coefficients of thermal expansion (CTE) of the electrically conductive oxide material 232 and the material of the second portions 216 (e.g., differing amounts of thermal expansion in a direction perpendicular to the top surfaces during subsequent annealing). For example, the CTE of ITO is about 5.8×10⁻⁶/K to 9×10⁻⁶/K while the CTE of silicon oxide is about 0.5×10⁻⁶/K. For comparison, the CTE of Cu is about 16.7×10⁻⁶/K. The thickness of the ITO can be selected to be thicker and the magnitude of the recess between the ITO and the neighboring silicon oxide can be more tightly controlled to account for the smaller CTE differential for ITO/SiO₂.

In this way, the first and second regions 234a, 236a can be formed and can be electrically isolated from one another without a patterning step. After planarization, the first substrate 210, including the first and second regions 234a, 236a of the first electrically conductive oxide layer 233a, can be cleaned (e.g., rinsed and spin dried) sufficiently for subsequent directly bonding.

While the example fabrication sequences of FIG. 7A is for fabricating the first substrate 210, starting with the first device 240 and the first layer 212, the same example fabrication sequences can be used for fabricating the second substrate 220, starting with the second device 250 and the second layer 222.

As schematically illustrated by FIG. 7B, directly bonding the first substrate 210 and the second substrate 220 with one another without an adhesive comprises contacting the first and second substrates 210, 220 with one another with the first and second electrically conductive oxide surface layers 233a, 233b therebetween (e.g., at room temperature; at temperatures below 35° C.). For example, as shown in FIG. 7B, the first electrically conductive oxide layer 233a and the second electrically conductive oxide layer 233b can be contacted with one another (e.g., with the first regions 234a, 234b contacting one another and the second regions 236a, 236b contacting one another). In addition, the first dielectric regions 720a of the first layer 212 and the second dielectric regions 720b of the second layer 222 can be contacted with one another and directly bonded to one another. For example, if the first dielectric regions 720a and/or the second dielectric regions 720b is polished and activated, the first and second dielectric regions 720a,b can bond to one another at room temperature (e.g., before annealing; before the first and second electrically conductive oxide layers 233a,b bond to one another). While FIG. 7B schematically illustrates certain implementations in which the second substrate 220 comprises the second electrically conductive oxide layer 233b over the second layer 222, in certain other implementations, the second substrate 220 does not comprise the second electrically conductive oxide layer 233b over the second layer 222, and directly bonding the first and second substrates 210, 220 with one another uses only the first electrically conductive oxide layer 233a between the first and second substrates 210, 220 (e.g., the first regions 234a in electrical contact with the first portions 214 and third portions 224 and the second regions 236a in contact with the second portions 216 and fourth portions 226). The alignment between the first regions 234 with the first and third portions 214, 224 and the alignment between the second regions 236 and the second and fourth portions 216, 226 can be sufficient to provide substantial electrical contact between the first and third portions 214, 224 where desired while avoiding electrically shorting the first regions 234 to one another (e.g., the alignment can be less than perfect).

In certain implementations, the method 500 can further comprise, after contacting the first and second substrates 210, 220 with one another, annealing the structure 200 (e.g., heating to a predetermined temperature higher than room temperature for a predetermined time period; at temperatures in a range of 150° C. to 300° C.). As explained above, the annealing process can cause the electrically conductive oxide layers 233a, 233b to expand to increase contact pressure between opposing conductive regions. Annealing can additionally or alternatively cause grain growth across the bond interface such that the grains can migrate at least partially into the opposing element. In certain implementations, the method 500 does not comprise activating (e.g., exposing to a plasma and/or chemical etchants) at least one of the first and second electrically conductive oxide layers 233a, 233b (e.g., both of the electrically conductive oxide layers 233a, 233b) after the cleaning. As shown in FIG. 7B, the periphery 260 of the structure 200 comprises the solid dielectric material 270 (e.g., silicon oxycarbonitride or SiOₓN_{y}C_{z}) which provides higher hermeticity to the components within the region bounded by the periphery 260 than would the at least one electrically conductive oxide material 232.

Beneficially, in certain implementations of the methods shown in FIGS. 6A-7B), the first and second substrates 210, 220 can be directly bonded without activating either substrate. For example, the first substrate 210 and the second substrate 220 may not be activated after the patterning of the conductive oxide layers 233a, 233b (which can serve as conductive contact features) and prior to the directly bonding. Additionally or alternatively, in certain implementations, at least one of the substrates 210, 220 may not be planarized after patterning the conductive oxide layers 233a, 233b and prior to the directly bonding. Omitting one or both of these steps can simplify the direct bonding process flow and reduce manufacturing costs. Without being limited by theory, the material properties of the conductive oxide layers 233a, 233b can form direct bonds after a low temperature anneal without requiring planarization and/or activation. As explained above, annealing can cause expansion of the conductive oxide layers 233a, 233b, and/or can cause grain growth to facilitate electrical connection between opposing conductive regions. In other embodiments, one or both substrates 210, 220 can be planarized and/or activated after patterning the layers 233a, 233b and before direct bonding.

FIG. 8A schematically illustrates an example fabrication sequence of the operational block 510 for providing the first substrate 210. The fabrication sequence of FIG. 8A is similar to that of FIG. 6A as described herein, but a solid dielectric layer 810 (e.g., either the same material as the second portion 216 or a different material) is over the portion of the first layer 212 (e.g., the electrically insulative second portion 216) that will be at the periphery 260 of the structure 200. As described herein with regard to FIG. 6A, providing the first substrate 210 in the operational block 510 can comprise depositing a first electrically conductive oxide layer 233a (e.g., ITO) over the first layer 212 (e.g., by sputtering, activated CVD, directional PVD, or ALD to a thickness on the order of microns). In certain implementations, after depositing the first electrically conductive oxide layer 233a, the first electrically conductive oxide layer 233a can be planarized (e.g., using CMP) to remove conductive oxide material 232 on the solid dielectric layer 810.

Providing the first substrate 210 in the operational block 510 can further comprise patterning the first electrically conductive oxide layer 233a to electrically isolate the first regions 234a from the second regions 236a. For example, as shown in FIG. 8A, a photoresist layer 610 can be deposited on the planarized first electrically conductive oxide layer 233a, the photoresist layer 610 can be patterned (e.g., using photolithographic techniques) to expose portions of the planarized first electrically conductive oxide layer 233a, and the exposed portions of the planarized first electrically conductive oxide layer 233a can be etched away to form gaps 238 between the first regions 234a and the second regions 236a (e.g., such that the second regions 236a do not electrically short the first regions 234a to one another). After etching, the remaining photoresist layer 610 can be stripped off and the first substrate 210, including the first and second regions 234a, 236a of the first electrically conductive oxide layer 233a, can be cleaned (e.g., rinsed and spin dried) sufficiently for subsequent directly bonding. While the example fabrication sequences of FIG. 8A is for fabricating the first substrate 210, starting with the first device 240 and the first layer 212, the same example fabrication sequences can be used for fabricating the second substrate 220, starting with the second device 250 and the second layer 222, with a solid dielectric layer 810 over the portion of the second layer 222 (e.g., the electrically insulative fourth portion 226) that will be at the periphery 260 of the structure 200 (e.g., either the same material as the fourth portion 226 or a different material).

As schematically illustrated by FIG. 8B, directly bonding the first substrate 210 and the second substrate 220 with one another without an adhesive can comprise contacting the first and second substrates 210, 220 with one another with the at least one electrically conductive oxide surface layer therebetween (e.g., at room temperature; at temperatures below 35° C.). While FIG. 8B schematically illustrates certain implementations in which the second substrate 220 comprises an electrically conductive oxide layer over the second layer 222, in certain other implementations, the second substrate 220 does not comprise an electrically conductive oxide layer over the second layer 222, and directly bonding the first and second substrates 210, 220 with one another uses only the first electrically conductive oxide layer 233a between the first and second substrates 210, 220 (e.g., the first regions 234a in electrical contact with the first portions 214 and third portions 224 and the second regions 236a in contact with the second portions 216 and fourth portions 226). The alignment between the first regions 234 with the first and third portions 214, 224 and the alignment between the second regions 236 and the second and fourth portions 216, 226 can be sufficient to provide substantial electrical contact between the first and third portions 214, 224 where desired while avoiding electrically shorting the first regions 234 to one another (e.g., the alignment can be less than perfect).

As described herein with regard to FIGS. 6B and 7B, the method 500 can further comprise, after contacting the first and second substrates 210, 220 with one another, annealing the structure 200 and/or not activating the electrically conductive oxide layer after the cleaning. As shown in FIG. 8B, the periphery 260 of the structure 200 comprises the solid dielectric layer 810, providing hermiticity to the components within the region bounded by the periphery 260.

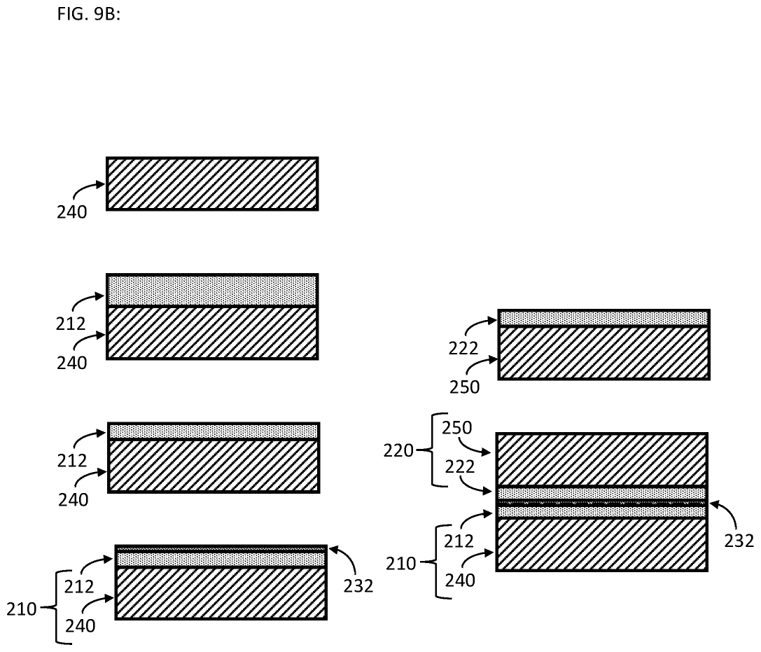

FIG. 9A is a schematic side sectional view of a bonded structure in accordance with certain implementations described herein. FIG. 9B is an example process flow in accordance with certain implementations described herein for forming the bonded structure of FIG. 9A. Unless otherwise noted, the components of FIGS. 9A-9B may be the same as or generally similar to like-numbered components of FIGS. 2A-4F and 6A-8B. However, unlike certain implementations described above, in FIGS. 9A-9B, the electrically conductive oxide material(s) 232 may be blanket deposited over one or both first and second substrates 210, 220, with portions of the electrically conductive oxide material 232 deposited on dielectric oxide materials electrically isolated from portions of the electrically conductive oxide material 232 deposited on electrically conductive materials (e.g., metal pads). For example, as shown in FIG. 7B, the first device 240 (which can comprise a semiconductor portion, such as a silicon portion) can be provided, and a first layer 212 comprising a first dielectric material can be deposited over the first device 240. The electrically conductive oxide material 232 can be deposited over the first dielectric material of the first layer 212. In certain implementations, the first dielectric material of the first layer 212 can comprise an inorganic dielectric, such as silicon oxide, silicon nitride, etc. In certain implementations, the second device 250 (which can comprise a semiconductor portion, such as a silicon portion) can be fabricated in a similar manner. For example, a second layer 222 comprising a second dielectric material can be deposited over the second device 250. In certain implementations, a portion of the conductive oxide material 232 can also be blanket deposited over the second dielectric material of the second layer 222. In certain implementations, the conductive oxide material 232 can be deposited only on the first substrate 210. The first and second substrates 210, 220 can be directly bonded to one another. In certain implementations, as explained above, neither the first nor second substrate 210, 220 may be activated prior to direct bonding. Additionally or alternatively, one or both of the first and second substrates 210, 220 may not be planarized or polished prior to direct bonding. In certain other implementations, however, one or both of the first and second substrates 210, 220 can be planarized and/or activated prior to direct bonding.

Table 1 lists example combinations of materials for the first regions 234a, 234b (e.g., the at least one conductive oxide material 232) and materials of the electrically conductive first and third portions 214, 224 of the first and second substrates 210, 220 in accordance with certain implementations described herein. Table 2 lists example combinations of materials for the second regions 236a, 236b (e.g., the at least one conductive oxide material 232) and materials of the electrically insulative second and fourth portions 216, 226 of the first and second substrates 210, 220 in accordance with certain implementations described herein. In each of Tables 1 and 2, absence of a listed material denotes that the at least one conductive oxide material 232 is only on one of the first and second substrates 210, 220 prior to contacting the first and second substrates 210, 220 to one another. Various stoichiometries of the at least one conductive oxide material 232 are compatible with certain implementations described herein and can play a role in the strength of the bond.

TABLE 1

| | | | | | | |
|---|---|---|---|---|---|---|
| First portion 214 | W | Co | ZnO | ZnO | W | Co |
| First regions 234a | ITO | ITO | ITO | ITO | ITO | ITO |
| First regions 234b | ITO | ITO | ITO | | | ZnO |
| Third portions 224 | W | W | ZnO | ZnO | ZnO | W |

TABLE 2

| | | | | | |
|---|---|---|---|---|---|
| Second portion 216 | SiO₂ | SiO₂ | SiN | SiO₂ | SiO₂ |
| Second regions 236a | ITO | ITO | ITO | ITO | ITO |
| Second regions 236b | ITO | | ITO | ZnO | ITO |
| Fourth portions 226 | SiO₂ | SiO₂ | SiO₂ | SiN | Cu/TiN |

In certain implementations, the bonded structures 200 can be coated with a protective layer, mounted on a dicing sheet, and singulated (e.g., by saw dicing, laser dicing, reactive ion etch dicing, wet etching, or a combination thereof) to form singulated dies on the dicing frame. The protective layer can be removed (e.g., stripped) from the singulated dies and the exposed dicing sheet (e.g., using solvent, reactive ion etching, etc.). The singulated die can be cleaned (e.g., rinsed and dried using spin drying or other processes). The cleaned dies can be configured for subsequent processes. For example, a cleaned die can be further bonded to a prepared surface of another substrate (e.g., comprising a power pad, ground pads, and/or other passive elements configured to transmit power to the bonded die).

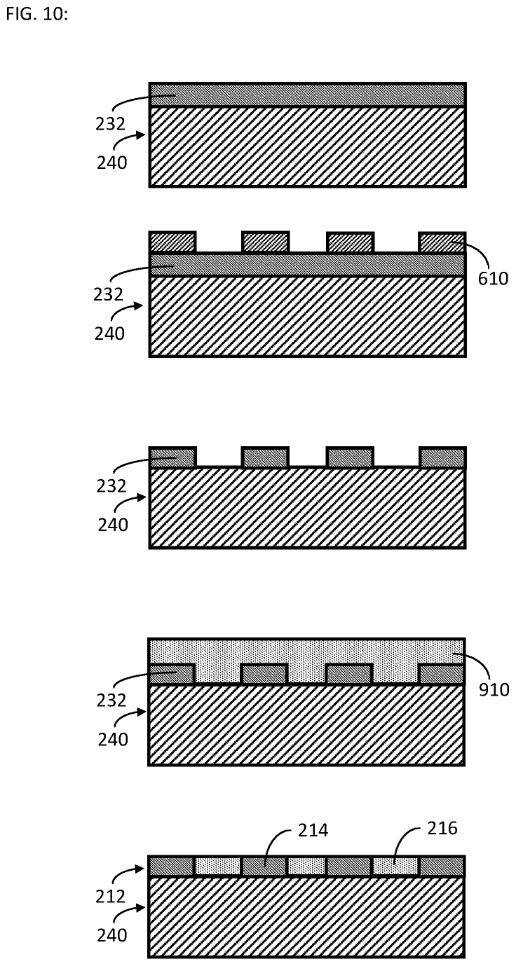

FIG. 10 schematically illustrates an example build-up process flow for forming the structure in accordance with certain implementations described herein. The at least one conductive oxide material 232 (e.g., ITO) can facilitate the build-up process flow. In addition, a similar process can be used to have a multi-layer metal layer as well (e.g., with transparent conductors above Cu or Al pads). For example, the at least one conductive oxide material 232 can be deposited onto a first substrate 210 or functional wafer device 240, a photoresist layer 610 can be deposited on the at least one conductive oxide material 232, the photoresist layer 610 can be patterned (e.g., using photolithographic techniques) to expose portions of the at least one conductive oxide material 232, and the exposed portions of the at least one conductive oxide material 232 can be etched away to form gaps. For example, patterning ITO can be performed using dilute HCl or HCl vapor in a plasma dry etch process or using Cl₂, BCl₃, CH₄, or H₂ as a dry etchant. After etching, the remaining photoresist layer 610 can be stripped off, and a dielectric layer 910 can be deposited over the at least one conductive oxide material 232 and the first substrate 210 or functional wafer device 240 within the gaps, and excess dielectric material can be removed (e.g., using CMP), leaving a planar first layer 212 for bonding, which can be cleaned (e.g., rinsed and spin dried) sufficiently for subsequent directly bonding. The planar first layer 212 can comprise the at least one conductive oxide material 232 as the first portions 214 and the dielectric material in the gaps as the second portions 216. The at least one conductive oxide material 232 can be configured to mate with active input/output pads on a second functional wafer device 250.

Although commonly used terms are used to describe the systems and methods of certain implementations for ease of understanding, these terms are used herein to be interpreted fairly. Although various aspects of the disclosure are described with regard to illustrative examples and implementations, the disclosed examples and implementations should not be construed as limiting. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without user input or prompting, whether these features, elements and/or steps are included or are to be performed in any particular implementation. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

It is to be appreciated that the implementations disclosed herein are not mutually exclusive and may be combined with one another in various arrangements. In addition, although the disclosed methods and apparatuses have largely been described in the context of direct bonding processes, various implementations described herein can be incorporated in a variety of other suitable devices, methods, and contexts.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within +10% of, within +5% of, within +2% of, within +1% of, or within +0.1% of the stated amount. As another example, the terms “generally parallel” and “substantially parallel” refer to a value, amount, or characteristic that departs from exactly parallel by +10 degrees, by +5 degrees, by +2 degrees, by +1 degree, or by +0.1 degree, and the terms “generally perpendicular” and “substantially perpendicular” refer to a value, amount, or characteristic that departs from exactly perpendicular by +10 degrees, by +5 degrees, by +2 degrees, by +1 degree, or by +0.1 degree. The ranges disclosed herein also encompass any and all overlap, sub-ranges, and combinations thereof. Language such as “up to,” “at least,” “greater than,” less than,” “between,” and the like includes the number recited. As used herein, the meaning of “a,” “an,” and “said” includes plural reference unless the context clearly dictates otherwise. Also, as used in the description herein, the meaning of “in” includes “into” and “on,” unless the context clearly dictates otherwise.

While the methods and systems are discussed herein in terms of elements labeled by ordinal adjectives (e.g., first, second, etc.), the ordinal adjective are used merely as labels to distinguish one element from another (e.g., one substrate from another or one surface layer from one another), and the ordinal adjective is not used to denote an order of these elements or of their use.

The disclosure described and claimed herein is not to be limited in scope by the specific example implementations herein disclosed, since these implementations are intended as illustrations, and not limitations, of several aspects of the disclosure. Any equivalent implementations are intended to be within the scope of this disclosure. Indeed, various modifications of the disclosure in form and detail, in addition to those shown and described herein, will become apparent to those skilled in the art from the foregoing description. Such modifications are also intended to fall within the scope of the claims. The breadth and scope of the disclosure should not be limited by any of the example implementations disclosed herein, but should be defined only in accordance with the claims and their equivalents.

1. A structure comprising:
a first substrate comprising a first layer having at least one electrically conductive first portion and at least one electrically insulative second portion;
a second substrate comprising a second layer having at least one electrically conductive third portion and at least one electrically insulative fourth portion; and
an interface layer between the first layer and the second layer, the interface layer comprising at least one electrically conductive oxide material, the at least one electrically conductive oxide material comprising:
at least one first region between and in electrical communication with the at least one electrically conductive first portion and the at least one electrically conductive third portion; and
at least one second region between the at least one electrically insulative second portion and the at least one electrically insulative fourth portion, the at least one second region electrically isolated from the at least one first region.

2. The structure of claim 1, wherein the at least one electrically conductive oxide material is optically transparent.

3. The structure of claim 2, wherein the at least one electrically conductive oxide material comprises indium tin oxide or zinc oxide.

4. The structure of claim 1, wherein the at least one electrically conductive oxide material comprises a first electrically conductive oxide material on the first layer and a second electrically conductive oxide material on the second layer, the first electrically conductive oxide material directly bonded to the second electrically conductive oxide material.

5. The structure of claim 1, wherein the at least one electrically conductive first portion and/or the at least one electrically conductive third portion is selected from the group consisting of: copper, tungsten, cobalt, or zinc oxide.

6. The structure of claim 1, wherein the at least one electrically insulative second portion and/or the at least one electrically insulative fourth portion is selected from the group consisting of: silicon oxide, silicon nitride, copper nitride, and titanium nitride.

7. The structure of claim 1, wherein the at least one first region is electrically isolated from the at least one second region.

8. The structure of claim 7, wherein a portion of the at least one electrically conductive oxide material at a periphery of the first and second substrates hermetically seals a second portion of the at least one electrically conductive oxide material from an ambient environment.

9. The structure of claim 7, further comprising gaps between the at least one first region and the at least one second region.

10. The structure of claim 9, wherein the at least one electrically conductive oxide material is not embedded within the at least one electrically insulative second portion and/or the at least one electrically insulative fourth portion.

11. The structure of claim 7, wherein the interface layer further comprises at least one solid dielectric material between the at least one first region and the at least one second region.

12. The structure of claim 11, wherein the at least one electrically conductive oxide material is embedded within the at least one electrically insulative second portion and/or the at least one electrically insulative fourth portion.

13. The structure of claim 11, wherein the at least one solid dielectric material comprises silicon oxycarbonitride.

14. The structure of claim 11, wherein a portion of the at least one solid dielectric material at a periphery of the first and second substrates hermetically seals the at least one first region and the at least one second region from an ambient environment.

15. The structure of claim 14, wherein the at least one solid dielectric material substantially surrounds the at least one first region and the at least one second region.

16. The structure of claim 11, wherein the at least one electrically conductive oxide material is embedded in the at least one solid dielectric material.

17.-25. (canceled)

26. A method comprising:
providing a first substrate and a second substrate each comprising one or more electrically conductive surface portions and one or more electrically insulative surface portions, at least one of the first substrate and the second substrate further comprising an electrically conductive oxide layer having a first region over and in electrical communication with the one or more electrically conductive surface portions and a second region over the one or more electrically insulative surface portions, the second region electrically isolated from the first region; and
directly bonding the first substrate and the second substrate with one another without an intervening adhesive, wherein directly bonding the first substrate and the second substrate comprises contacting the first substrate and the second substrate with one another with the electrically conductive oxide layer therebetween.

27. The method of claim 26, wherein providing the first substrate comprises:
depositing a first electrically conductive oxide layer over the one or more electrically conductive surface portions and the one or more electrically insulative surface portions; and
patterning the first electrically conductive oxide layer to electrically isolate the first region from the second region.

28. The method of claim 27, wherein providing the second substrate comprises:
depositing a second electrically conductive oxide layer over the one or more electrically conductive surface portions and the one or more electrically insulative surface portions; and
patterning the second electrically conductive oxide layer to electrically isolate the first region from the second region.

29. The method of claim 28, wherein directly bonding the first substrate and the second substrate further comprises contacting the first patterned electrically conductive oxide layer and the second patterned electrically conductive oxide layer with one another.

30. The method of claim 27, wherein patterning the first electrically conductive oxide layer comprises:
depositing a photoresist layer over the deposited first electrically conductive oxide layer;
patterning the photoresist layer to expose portions of the first electrically conductive oxide layer;
etching away the exposed portions of the first electrically conductive oxide layer; and
stripping off the photoresist layer.

31. The method of claim 27, wherein patterning the first electrically conductive oxide layer comprises planarizing the first electrically conductive oxide layer.

32. The method of claim 31, wherein the one or more electrically conductive surface portions have recesses relative to the one or more electrically insulative surface portions, wherein depositing the first electrically conductive oxide layer comprises filling the recesses with the first electrically conductive oxide layer, and wherein planarizing the first electrically conductive oxide layer comprises removing portions of the first electrically conductive oxide layer that are outside the recesses.

33. The method of claim 31, wherein the one or more electrically insulative surface regions have recesses, wherein depositing the first electrically conductive oxide layer comprises filling the recesses with the first electrically conductive oxide layer, and wherein planarizing the first electrically conductive oxide layer comprises removing portions of the first electrically conductive oxide layer that are outside the recesses.

34. The method of claim 33, further comprising:
depositing a photoresist layer over the planarized first electrically conductive oxide layer;
patterning the photoresist layer to expose portions of the planarized first electrically conductive oxide layer;
etching away the exposed portions of the planarized first electrically conductive oxide layer; and
stripping off the photoresist layer.

35. The method of claim 26, further comprising cleaning at least one of the first and second substrates prior to contacting the first and second substrates with one another.

36. The method of claim 26, further comprising annealing the first and second substrates after contacting the first and second substrates with one another.

37.-104. (canceled)
